(19) United States
(12) Patent Application Publication
(10) Pub. No.: US 2010/0103651 A1
(43) Pub. Date: Apr. 29, 2010

(54) LED MODULE AND BACKLIGHT UNIT HAVING THE SAME

(75) Inventor: Jun Seok Park, Gwangju (KR)

Correspondence Address: BIRCH STEWART KOLASCH & BIRCH, PO BOX 747, FALLS CHURCH, VA, 22040-0747, US

(73) Assignee: LG Innotek Co., Ltd., Seoul (KR)

(21) Appl. No.: 12/532,105

(22) PCT Filed: Mar. 18, 2008
(86) PCT No.: PCT/KR08/01522

§ 371 Date: Sep. 18, 2009

(30) Foreign Application Priority Data
Mar. 19, 2007 (KR) 10-2007-0026848

(51) Int. Cl. G09F 13/04; H05K 1/11; H05K 7/20

(52) U.S. Cl. 362/97.1; 361/803; 361/707

(57) ABSTRACT

The LED module comprises a first and a second printed circuit boards comprising one surface formed with at least one of concave and convex parts so that the first and the second printed circuit boards are coupled to each other, and an LED on at least one of the first and the second printed circuit boards, in which a concave part is formed at a portion of a coupling surface of the second printed circuit board corresponding to a convex part formed at a portion of a coupling surface of the first printed circuit board, and an insulating layer is formed at a portion of the coupling surface of the second printed circuit board so as to support a convex part of the first printed circuit board.

### TECHNICAL FIELD

The embodiment relates to an LED module and a backlight unit having the same.

### BACKGROUND ART

FIG. 1 is a view schematically showing a portion of a related art backlight unit, and FIG. 2 is a sectional view taken along line I-I′ of FIG. 1.

As shown in FIGS. 1 and 2, the related art backlight unit comprises a case 10, an LED module 20 and a fixing unit 30.

The LED module 20 providing light comprises a printed circuit board 21, an LED 23 formed on the printed circuit board 21, and a mold part 25 formed on the LED 23. The LED module 20 is formed thereon with a reflective sheet comprising an opening such that the LED 23 can be exposed. The reflective sheet reflects light emitted from the LED 23 upward. The fixing unit 30 fixes the LED module 20 to the case 10. The backlight unit comprising the above structure comprises a plurality of the LED modules 20.

In addition, as shown in FIG. 3, an LED module may comprise a plurality of printed circuit boards 41, 43, and 45. FIG. 3 is a schematic view showing the connections between the printed circuit boards in the LED module employed for the related art backlight unit.

The printed circuit boards 41, 43, and 45 may be mechanically and electrically connected to each other. For example, the printed circuit boards 41, 43, and 45 may be electrically connected to each other through connection parts 47 and 49. In order to electrically connect the printed circuit boards 41, 43, and 45 to each other through the connection parts 47 and 49, a heat treatment process such as an SMT reflow process is performed.

However, when the heat treatment process such as the SMT reflow process is performed, LEDs formed on a printed circuit board may be damaged. In addition, when defects occur in one of the printed circuit boards, the entire LED module must be replaced.

### DISCLOSURE OF INVENTION

### Technical Problem

The embodiment provides an LED module comprising a plurality of printed circuit boards and a backlight unit comprising the LED module, in which the printed circuit boards are electrically and mechanically coupled to each other with stability, and only the defected printed circuit board can be easily replaced when defects occur in one of the printed circuit boards.

### Technical Solution

According to the embodiment, an LED module comprises a first and a second printed circuit boards comprising one surface formed with at least one of concave and convex parts so that the first and second printed circuit boards are coupled to each other, and an LED on at least one of the first and the second printed circuit boards, wherein a concave part is formed at a portion of a coupling surface of the second printed circuit board corresponding to a convex part formed at a portion of a coupling surface of the first printed circuit board, and an insulating layer is formed at a portion of the coupling surface of the second printed circuit board so as to support a convex part of the first printed circuit board.

According to the embodiment, a backlight unit comprises an LED module comprising a first and a second printed circuit boards comprising one surface formed with at least one of concave and convex parts so that the first and the second printed circuit boards are coupled to each other, and an LED on at least one of the first and the second printed circuit boards, in which a concave part is formed at a portion of a coupling surface of the second printed circuit board corresponding to a convex part formed at a portion of a coupling surface of the first printed circuit board, and an insulating layer is formed at a portion of the coupling surface of the second printed circuit board so as to support a convex part of the first printed circuit board, and a reflective sheet comprising an opening on the LED module such that the LED is exposed.

According to the embodiment, an LED module comprises a first and a second printed circuit boards comprising one surface formed with at least one of concave and convex parts so that the first and second printed circuit boards are coupled to each other, and an LED on at least one of the first and the second printed circuit boards, wherein a concave part is formed at a portion of a coupling surface of the second printed circuit board corresponding to a convex part formed at a portion of a coupling surface of the first printed circuit board, and the first and second printed circuit boards are electrically connected to each other through the convex and concave parts, and a conductive layer is formed on a sidewall of the convex and concave parts.

### ADVANTAGEOUS EFFECTS

In an LED module comprising a plurality of printed circuit boards and a backlight unit comprising the LED module according to the embodiment, the printed circuit boards are electrically and mechanically coupled to each other with stability. If defects occur in one of the printed circuit boards, only the defected printed circuit board can be easily replaced.

### BRIEF DESCRIPTION OF THE DRAWINGS

FIG. 1 is a view schematically showing a portion of a related art backlight unit;

FIG. 2 is a sectional view taken along line I-I′ of FIG. 1;

FIG. 3 is a view schematically showing the connection between printed circuit boards in an LED module employed for a related art backlight unit;

FIG. 4 is a view schematically showing the connection between printed circuit boards in an LED module according to the embodiment;

FIGS. 5 to 9 are views showing printed circuit boards employed for an LED module according to the embodiment;

FIG. 10 is a sectional view showing the structure of a printed circuit board employed for an LED module according to the embodiment; and

FIG. 11 is a view schematically showing the stack structure of connection parts between printed circuit boards employed for an LED module according to the embodiment.

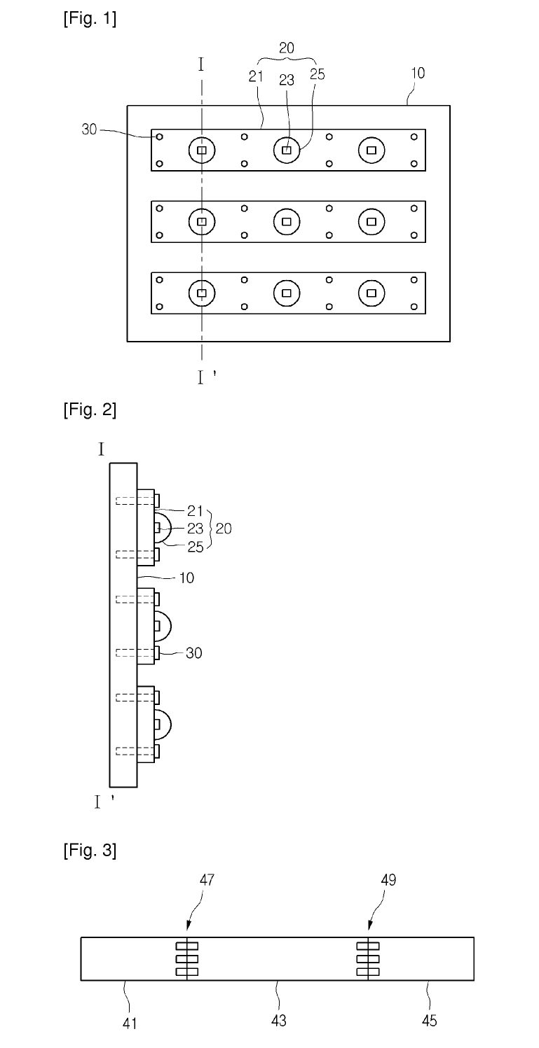

### MODE FOR THE INVENTION

It will be understood that when a substrate, a layer (film), a region, a pattern, or a structure are referred to as being “on” or “under” another substrate, layer, region, pad or pattern, they can directly contact the other substrate, layer, region, pad or pattern, or intervening layers, regions, pads, patterns or structures may also be present. The meaning must be understood based on the spirit and scope of the principles of this disclosure.

Hereinafter, the embodiment will be described with reference to accompanying drawings.

LED module according to the embodiment comprises a plurality of printed circuit boards. The printed circuit boards are formed on at least one surface thereof with concave/convex parts. The LED module according to the embodiment comprises the printed circuit boards, which are coupled to each other through the concave/convex parts formed at the surfaces of the printed circuit boards, and LEDs formed on the printed circuit boards.

The printed circuit boards may be mechanically coupled to each other with stability through the coupling of the concave/convex parts. In addition, the printed circuit boards may be electrically connected to each other. The concave/convex parts may be realized such that the convex part can be press-fitted into the concave part. An internal area, which comprises a width wider than that of an inlet part engaged with the convex section, exists in the concave part of the printed circuit boards. The convex part is press-fitted into the concave part. Therefore, the concave part may not be slidably separated from the convex part.

The concave/convex parts may comprise various shapes and a preferred thickness, thereby ensuring mechanical stability. In addition, as one example, conductive layers may be formed on the wall surfaces of the concave/convex parts, so that the printed circuit boards can be electrically connected to each other through the coupling of the concave and convex parts.

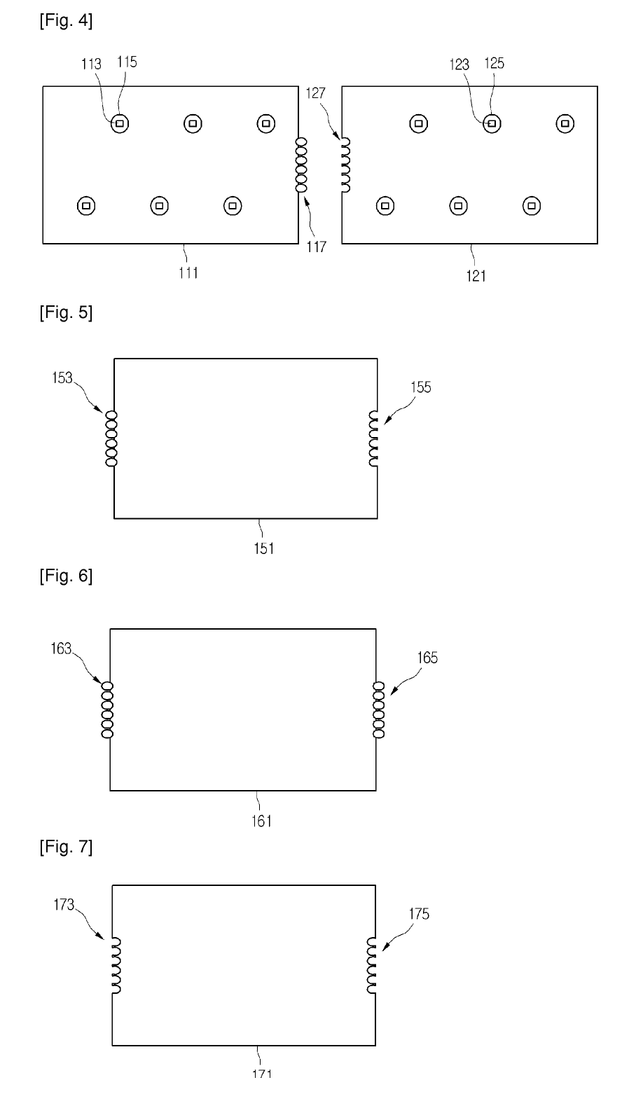

FIG. 4 is a view schematically showing the state of the connection between the printed circuit boards in an LED module according to the embodiment.

As shown in FIG. 4, in the LED module according to the embodiment, two printed circuit boards 111 and 121 may be coupled to each other by using the convex part 117 and the concave part 127. The convex part 117 is formed on the side surface of the first printed circuit board 111. The concave part 127 is formed on the side surface of the second printed circuit board 121.

The printed circuit boards 111 and 121 may comprise a poly resin substrate, an epoxy resin substrate, a composite substrate, a ceramic substrate, or a metal substrate. For example, the printed circuit boards 111 and 121 may comprise an FR4 PCB, a metal PCB, or a CM3 PCB.

The printed circuit boards 111 and 121 may be formed thereon with plural LEDs 113 and 123. The plural LEDs 113 and 123 may be formed thereon mold parts 115 and 125. The LEDs 113 and 123 may comprise at least one of red, green, blue, and white LEDs. The mold parts 115 and 125 can adjust the propagation direction of light emitted from the LEDs 113 and 123 and protect the LEDs 113 and 123.

The concave/convex parts 127 and 117 may comprise various shapes. The concave/convex shapes may be realized to coupled each other by press-fitting a convex part 127 into a concave part 117. An internal area, which has a width wider than that of an inlet part engaged with the convex part, exists in the concave part of the printed circuit boards. The convex part is press-fitted into the concave part. Accordingly, the coupled concave part and the convex part may not be separated from each other through sliding movement.

The concave/convex parts 127 and 117 comprise a preferred thickness, thereby ensuring mechanical stability. For an example, the concave/convex parts 127 and 117 may comprise a thickness in the range of 0.5 mm to 20 mm. The concave/convex parts 127 and 117 may comprise a thickness that deviates from the above range according to the design of the LED module or when it is necessary.

The printed circuit boards 111 and 121 are electrically connected to each other through the concave/convex parts 127 and 117. For example, conductive layers may be formed on the wall surfaces of the concave/convex parts 127 and 117, such that the printed circuit boards 111 and 121 are electrically connected to each other through the coupling of the concave/convex parts 127 and 117. The conductive layers formed on the wall surfaces of the concave/convex parts 127 and 117 may comprise a solder pattern.

The concave/convex parts 127 and 117 may comprise various geometrical shapes and may be selectively formed in the printed circuit boards. Further, a plurality of concave/convex parts 127 and 117 may be provided. FIGS. 5 to 9 are views showing examples of printed circuit boards employed for an LED module according to the embodiment.

FIG. 5 shows convex/concave parts 153 and 155 of a first printed circuit board 151, in which the convex part 153 is formed at the first side of the first printed circuit board 151, and the concave part 155 is formed at the second side of the first printed circuit board 151. A second printed circuit board coupled to the printed circuit board 151 through the convex part 153 comprises a concave part. In addition, a third printed circuit board coupled to the printed circuit board 151 through the concave part 155 comprises a convex part.

FIG. 6 shows convex parts 163 and 165 formed at the first and second side surfaces of a first printed circuit board 161. A second printed circuit board coupled to the first printed circuit board 161 through the convex part 163 comprises a concave part. In addition, a third printed circuit board coupled to the first printed circuit board 161 through the convex part 165 comprises a concave part.

FIG. 7 shows concave parts 173 and 175 formed at first and second side surfaces of a first printed circuit board 171. A second printed circuit board coupled to the first printed circuit board 171 through the concave part 173 comprises a convex part, and a third printed circuit board coupled to the first printed circuit board 171 through the concave part 175 comprises a convex part.

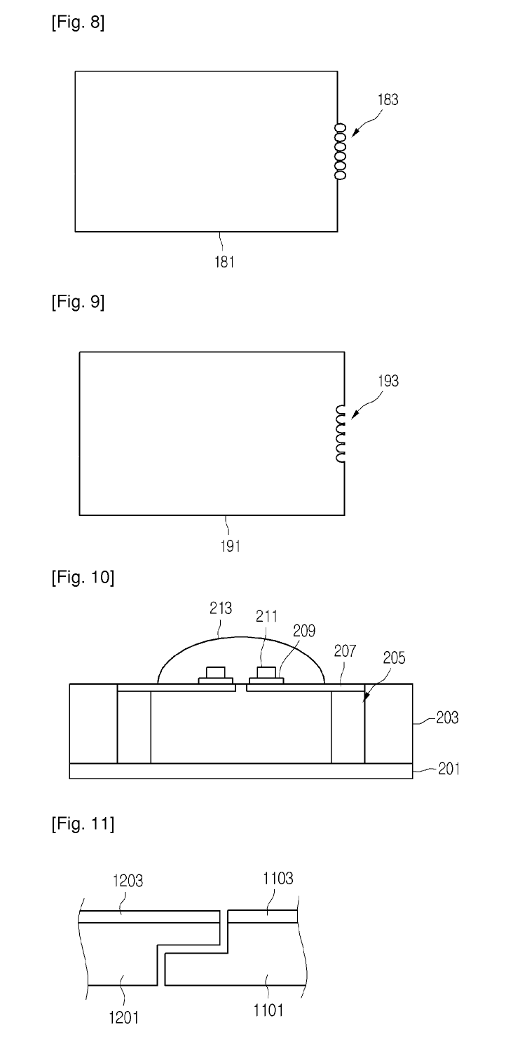

FIGS. 8 and 9 show convex/concave parts 183 and 193 formed only at the first side surfaces of printed circuit boards 181 and 191. When a plurality of printed circuit boards are coupled to each other, the printed circuit boards provided at the ends of the coupling structure may comprise the convex/concave parts 183 and 193 only at the first side surface coupled to adjacent printed circuit boards as shown in FIGS. 8 and 9.

In the LED module according to the embodiment, an additional heat treatment process such as an SMT reflow process is not required for coupling a plurality of printed circuit boards to each other. Accordingly, it is possible to prevent LEDs from being damaged due to the heat treatment process such as the SMT reflow process. In addition, when defects occur in one of the printed circuit boards, only the defected printed circuit board is replaced with a new one, and remaining printed circuit boards constructing the LED module may be maintained. In the LED module according to the embodiment, a plurality of printed circuit boards may be electrically and mechanically coupled to each other with stability. In addition, when defects occur in one of the printed circuit boards, only the defected printed circuit board may be easily replaced.

Meanwhile, for illustrative purposes, the printed circuit boards may comprise a structure as shown in FIG. 10. FIG. 10 is a sectional view schematically showing the structure of the printed circuit board employed for the LED module according to the embodiment.

As shown in FIG. 10, the printed circuit board according to the embodiment comprises a metal layer 201, an insulating layer 203, and a metal pad 207.

The insulating layer 203 is formed on the metal layer 201, and may comprise a through hole 205 formed in the printed circuit board. The through hole 205 may be filled with a heat conductive material. In addition, the heat conductive material may be coated on the inner walls of the through hole 205. In this manner, the metal layer 201 may be connected to the metal pad 207 by the through hole 205. Although the metal pad 207 is connected as a whole in FIG. 10, the metal pad 207 can be also partially divided.

An LED 211 may be formed on the metal pad 207, and a mold part 213 may be formed on the LED 211. The LED 211 comprises at least one of a red LED, a green LED, a blue LED, and a white LED. The mold part 213 may adjust the propagation direction of light emitted from the LED 211 and protect the LED 211. The LED 211 may be bonded to the metal pad 207 by using a conductive bonding element 209. The conductive bonding element 209 comprises a material such as a silver paste.

For example, the metal pad 207 and the metal layer 201 may comprise copper. The metal pad 207 is connected to the metal layer 201 by using a heat conductive material, so that the heat radiated from the LED 211 may be easily transmitted to the metal layer 201 via the through hole 205. Accordingly, the heat generated from the LED 211 on the metal pad 207 can be effectively dissipated through the metal layer 201.

Meanwhile, at least one concave/convex part is formed at the side of a printed circuit board according to the embodiment so that the printed circuit board is coupled to an adjacent printed circuit board. In this case, the concave/convex part on the printed circuit board may comprise the same thickness as that of the printed circuit board. In addition, in order to ensure mechanical stability, the concave/convex part may comprise a structure as shown in FIG. 11. FIG. 11 is a view showing a stacked structure of connection parts between printed circuit boards employed for the LED module according to the embodiment.

As shown in FIG. 11, a first and a second printed circuit boards comprising an insulating layer 1101 and 1201, and a metal pad 1103 and 1203 may be coupled to each other. A supporting part may be formed as the insulating layer 1101 at the coupling area.

A concave part is formed at the first side surface of the second printed circuit board corresponding to a convex part formed at the first side surface of the first printed circuit board. A supporting part for supporting the convex part of the first printed circuit board may be formed on the area of the concave part of the second printed circuit board. And a supporting part may be formed as an insulating layer.

In addition, the convex part is formed at the upper portion of the coupling surface of the first printed circuit board. The concave part is formed at the upper portion of the coupling surface of the second printed circuit board corresponding to the convex part of the first printed circuit board. In addition, a protrusion part is formed at the lower portion of the coupling surface of the second printed circuit board to support the convex part of the first printed circuit board. The protrusion may be formed of the insulating layer 1101.

The above LED module according to the embodiment is adaptable for a backlight unit.

A backlight unit according to the embodiment comprises the LED module and a reflective sheet formed on the LED module and comprising an opening such that the LED may be exposed. The reflective sheet reflects light emitted from the LED upward.

In addition, the above LED module according to the embodiment is adaptable for various display devices.

A display device according to the embodiment comprises the above LED module and a display unit displaying an image by using light generated from the LED module. The display device may comprise a reflective sheet formed on the LED module and comprising an opening such that the LED may be exposed. The reflective sheet may reflect the light generated from the LED onto the display unit. The display unit may be a liquid crystal panel as one example.

Any reference in this specification to “one embodiment”, “an embodiment”, “example embodiment” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

In an LED module comprising a plurality of printed circuit boards and a backlight unit comprising the LED module according to the embodiment, the printed circuit boards are electrically and mechanically coupled to each other with stability. If defects occur in one of the printed circuit boards, only the defected printed circuit board can be easily replaced with new one.

1. An LED module comprising:
a first and a second printed circuit boards comprising one surface formed with at least one of concave and convex parts so that the first and the second printed circuit boards are coupled to each other; and
an LED on at least one of the first and the second printed circuit boards,
wherein a concave part is formed at a portion of a coupling surface of the second printed circuit board corresponding to a convex part formed at a portion of a coupling surface of the first printed circuit board, and an insulating layer is formed at a portion of the coupling surface of the second printed circuit board so as to support a convex part of the first printed circuit board.

2. The LED module as claimed in claim 1, wherein the first and the second printed circuit boards are electrically connected to each other by using the concave and convex parts, and a conductive layer is formed on a sidewall of the concave and convex parts.

3. The LED module as claimed in claim 1, wherein each one of the first and the second printed circuit boards comprises:
a metal layer;
an insulating layer comprising a through hole on the metal layer; and
a metal pad formed on the insulating layer and connected to the metal layer through the through hole.

4. The LED module as claimed in claim 3, wherein the through hole is filled with a heat conductive material.

5. The LED module as claimed in claim 3, wherein a heat conductive material is coated on an inner wall of the through hole.

6. The LED module as claimed in claim 3, wherein heat emitted from the LED on the metal pad is transmitted into the metal layer via the through hole and then dissipated.

7. The LED module as claimed in claim 1, wherein the concave part of the second printed circuit board comprises an internal area comprising a width wider than that of an inlet part engaged with the convex part, and the convex part is press-fitted with the concave part.

8. The LED module as claimed in claim 1, wherein the printed circuit board comprises at least one of FR4, Metal, and CM3.

9. A backlight unit comprising:
an LED module, which comprises: a first and a second printed circuit boards comprising one surface formed with at least one of concave and convex parts so that the first and the second printed circuit boards are coupled to each other; and
an LED on at least one of the first and the second printed circuit boards, in which a concave part is formed at a portion of a coupling surface of the second printed circuit board corresponding to a convex part formed at a portion of a coupling surface of the first printed circuit board, and an insulating layer is formed at a portion of the coupling surface of the second printed circuit board so as to support a convex part of the first printed circuit board; and
a reflective sheet comprising an opening on the LED module such that the LED is exposed.

10. The backlight unit as claimed in claim 9, wherein the first and the second printed circuit boards are electrically connected to each other by using the concave and convex parts, and a conductive layer is formed on a sidewall of the concave and convex parts.

11. The backlight unit as claimed in claim 9, wherein each one of the first and the second printed circuit boards comprises:
a metal layer;
an insulating layer comprising a through hole on the metal layer; and
a metal pad formed on the insulating layer and connected to the metal layer through the through hole.

12. The backlight unit as claimed in claim 11, wherein the through hole is filled with a heat conductive material.

13. The backlight unit as claimed in claim 11, wherein a heat conductive material is coated on an inner wall of the through hole.

14. The backlight unit as claimed in claim 11, wherein heat emitted from the LED on the metal pad is transmitted into the metal layer via the through hole and then dissipated.

15. The backlight unit as claimed in claim 9, wherein the concave part of the second printed circuit board comprises an internal area comprising a width wider than that of an inlet part engaged with the convex part, and the convex part is press-fitted with the concave part.

16. An LED module comprises:
A first and a second printed circuit boards comprising one surface formed with at least one of concave and convex parts so that the first and the second printed circuit boards are coupled to each other; and
an LED on at least one of the first and the second printed circuit boards,
wherein a concave part is formed at a portion of a coupling surface of the second printed circuit board corresponding to a convex part formed at a portion of a coupling surface of the first printed circuit board, and the first and the second printed circuit boards are electrically connected to each other through the convex and concave parts, and a conductive layer is formed on a sidewall of the convex and concave parts.

17. The LED module as claimed in claim 16, wherein each one of the first and the second printed circuit boards comprises:
a metal layer;
an insulating layer comprising a through hole on the metal layer; and
a metal pad formed on the insulating layer and connected to the metal layer through the through hole.

18. The LED module as claimed in claim 17, wherein heat emitted from the LED on the metal pad is transmitted into the metal layer via the through hole and then dissipated.
